(19) United States
(12) Patent Application Publication
(10) Pub. No.: US 2006/0273371 A1
(43) Pub. Date: Dec. 7, 2006

(54) Evaluation semiconductor device

(75) Inventors: Yoko Tohyama, Kyoto (JP); Yasutoshi Okuno, Kyoto (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/367,549

(22) Filed: Mar. 6, 2006

(30) Foreign Application Priority Data
Jun. 7, 2005 (JP) 2005-166641

(51) Int. Cl. H01L 27/108

(52) U.S. Cl. 257/303

(57) ABSTRACT

An evaluation semiconductor device is used for evaluating a yield of a DRAM portion of an integrated circuit device. The evaluation semiconductor device includes an evaluation gate interconnect provided in a layer corresponding to a gate interconnect layer of the DRAM portion; and an evaluation source contact corresponding to a source contact of a capacitor included in the DRAM portion and connected to the evaluation gate interconnect.

### BACKGROUND OF THE INVENTION

The present invention relates to an evaluation semiconductor device (TEG: test element group) provided with appropriate interconnects for obtaining a yield of a semiconductor integrated circuit device including a capacitor cell as a product of process yields attained in respective principal mask layer.

In fabrication of semiconductor devices such as LSIs, the cost for the semiconductor devices can be lowered by obtaining a large number of good LSIs from one semiconductor substrate (semiconductor wafer), namely, by improving the yield. On the other hand, one of known causes to lower the yield is, for example, a defect such as a foreign matter caused in each process (wiring process in particular) of the LSI fabrication process, which leads to a short or an open or a formation failure of a capacitor. The density of defects such as a foreign matter can be estimated on the basis of, for example, dust distribution information of a clean room where the LSIs are fabricated. It is noted that as the chip size of the LSI is larger, the number of defects such as a foreign matter occurring in one LSI chip is larger, and hence, the yield is lowered.

It is significant for estimating the fabrication cost of the LSI to calculate such a yield of the LSI at design stage.

Therefore, with respect to a yield in consideration of an open or a short of interconnects, a method for estimating fraction defective of the interconnects by using a TEG with, for example, a comb and snake pattern (see Non-patent literature 1). Specifically, process control technique in which abnormal occurring in each semiconductor fabrication process is detected at an early stage by forming such a pattern in a short loop (that is, a part of the fabrication process) is generally widely employed.

In fabrication of capacitor cells included in a DRAM (dynamic random access memory), however, since the same pattern is repeated therein and it is difficult to calculate a yield of each layer directly in their shapes, the following technique is mainly employed: A TEG for the DRAM portion having a layout the same as that used in an actual product is repeatedly formed, and a problem to be solved for improving the yield is extracted by bit failure map analysis or the like by using the TEG.

On the other hand, Patent Literature 1 describes a method for calculating yields attained in respective principal layer processes by evaluating electric characteristics of a TEG obtained by ending midway diffusion process for a DRAM.

Non-Patent Literature 1: Lee Jacobson (National Semiconductor Corp.) et al., Development of Dynamic Tool PID/PWP Limits to Achieve Product Defect Density Goal, 1997, IEEE/SEMI Advanced Semiconductor Manufacturing Conference, pp. 144-145 Patent Literature 1: U.S. Pat. No. 5,872,018

### SUMMARY OF THE INVENTION

However, in the case where the TEG for the DRAM portion having the same layout as that of an actual product is repeatedly formed as in the aforementioned conventional method, the formation of the TEG takes time. Therefore, when a problem actually arises in a process, it takes time to detect the problem, and hence, practice of a countermeasure is disadvantageously late.

Also, in the method described in Patent Literature 1, resistance between bit lines or word lines formed on a capacitor cell structure is measured in the middle of the fabrication, and therefore, as compared with the case where defect analysis is performed on the basis of a test result of an ultimate product, failures can be detected advantageously earlier. However, it is impossible to employ the method of Patent Literature 1 for evaluating detection results dividedly in respective processes in forming the capacitor cell.

In consideration of the aforementioned conventional disadvantages, an object of the invention is evaluating a yield attained in each process for a DRAM portion of an integrated circuit device at an early stage.

In order to achieve the object, the present inventors have devised use of a TEG provided with necessary interconnects as a mask layer disposed on or beneath a mask layer to be calculated for the yield, so as to obtain the yield of the DRAM portion of the integrated circuit device as a product of yields (fraction defectives) attained in processes respectively corresponding to principal mask layers. Specifically, for measuring a leakage current or the like between a plurality of capacitor cells each formed in the shape of an island, a device in which a minimally necessary evaluation interconnect is additionally provided to an interconnect layer disposed on or beneath each capacitor cell is used as a TEG.

Specifically, the first evaluation semiconductor device of this invention for evaluating a yield of a DRAM portion of an integrated circuit device, includes an evaluation gate interconnect provided in a layer corresponding to a gate interconnect layer of the DRAM portion; and an evaluation source contact corresponding to a source contact of a capacitor included in the DRAM portion and connected to the evaluation gate interconnect. The first evaluation semiconductor device may further include a plurality of elements of the capacitor provided on or above the evaluation gate interconnect.

According to the first evaluation semiconductor device, each of a short between storage plates along the X-direction (for example, the bit line direction; which is also applied to description below) or the Y-direction (for example, the word line direction; which is also applied to the description below), an open between a storage plate and a source contact, an open between a source contact and a bit line contact and a short between source contacts occurring in capacitor forming process (including related processing; which is also applied to the description below) can be evaluated.

Preferably, in the first evaluation semiconductor device, the evaluation gate interconnect includes at least a first evaluation gate interconnect and a second evaluation gate interconnect, the evaluation source contact includes at least a first evaluation source contact connected to the first evaluation gate interconnect and a second evaluation source contact connected to the second evaluation gate interconnect, and evaluation storage plates corresponding to a storage plate of the capacitor are respectively formed on the first evaluation source contact and the second evaluation source contact.

Thus, the X-direction or Y-direction short between storage plates caused in the capacitor forming process can be evaluated by evaluating whether or not a short is caused between the first evaluation gate interconnect and the second evaluation gate interconnect.

Preferably, in the first evaluation semiconductor device, the evaluation gate interconnect includes at least a first evaluation gate interconnect and a second evaluation gate interconnect, the evaluation source contact includes at least a first evaluation source contact connected to the first evaluation gate interconnect and a second evaluation source contact connected to the second evaluation gate interconnect, and an evaluation storage plate corresponding to a storage plate of the capacitor is formed for connecting the first evaluation source contact and the second evaluation source contact to each other.

Thus, the open between a storage plate and a source contact caused in the capacitor forming process can be evaluated by evaluating whether or not the first evaluation gate interconnect and the second evaluation gate interconnect are conductive.

Preferably, in the first evaluation semiconductor device, the evaluation gate interconnect includes at least a first evaluation gate interconnect and a second evaluation gate interconnect, the evaluation source contact includes at least a first evaluation source contact connected to the first evaluation gate interconnect and a second evaluation source contact connected to the second evaluation gate interconnect, an evaluation bit line corresponding to a bit line of the DRAM portion is formed for electrically connecting the first evaluation source contact and the second evaluation source contact to each other, the first evaluation source contact and the evaluation bit line are connected to each other through a first evaluation bit line contact corresponding to a bit line contact of the DRAM portion, and the second evaluation source contact and the evaluation bit line are connected to each other through a second evaluation bit line contact corresponding to the bit line contact of the DRAM portion.

Thus, the open between a source contact and a bit line contact caused in the capacitor forming process can be evaluated by evaluating whether or not the first evaluation gate interconnect and the second evaluation gate interconnect are conductive.

Preferably, in the first evaluation semiconductor device, the evaluation gate interconnect includes at least a first evaluation gate interconnect and a second evaluation gate interconnect, and the evaluation source contact includes at least a first evaluation source contact formed on the first evaluation gate interconnect and a second evaluation source contact formed on the second evaluation gate interconnect.

Thus, the short between source contacts caused in the capacitor forming process can be evaluated by evaluating whether or not a short is caused between the first evaluation gate interconnect and the second evaluation gate interconnect.

The second evaluation semiconductor device of this invention for evaluating a yield of a DRAM portion of an integrated circuit device, includes a first evaluation bit line and a second evaluation bit line provided in a layer corresponding to a bit line layer of the DRAM portion, and the first evaluation bit line is electrically connected to an evaluation bit line contact corresponding to a bit line contact of the DRAM portion and the second evaluation bit line is electrically connected to an evaluation upper cell plate corresponding to an upper cell plate of a capacitor included in the DRAM portion.

According to the second evaluation semiconductor device, the short between an upper cell plate and a bit line contact caused in the capacitor forming process can be evaluated by evaluating whether or not a short is caused between the first evaluation bit line and the second evaluation bit line.

Furthermore, the performance of a current measurement apparatus is recently improved and hence the accuracy and the speed for measuring a current are largely improved. Therefore, when a large number of small-scaled patterns are included in each test group element of the invention, a soft open or a soft short, which is conventionally impossible to detect, can be detected and evaluated.

Moreover, when the yield evaluation result of each layer per unit capacity is obtained by using each evaluation semiconductor device of this invention, the yield of a whole chip can be estimated on the basis of the capacity of an actual product.

Also, when the yield of each layer is evaluated by using the evaluation semiconductor device of the invention, the respective processes for the fabrication of a DRAM can be developed in parallel, and hence, TAT (turn-around-time) of the process development can be shortened.

Furthermore, when the relationship between the yield obtained by using the evaluation semiconductor device of the invention and the yield of each failure item of an actual product is previously found, the yield of each process can be calculated on the basis of the yield of the failure item in the fabrication of the actual product. Specifically, even when there arises a problem of lowering of the yield or the like in the mass-production of the actual product, a process possibly causing the problem can be found on the basis of the yield of each failure item, and hence, the problem can be coped with at an early stage.

In this manner, according to the invention, the yield of the DRAM portion of the integrated circuit device can be obtained as a product of the yields attained in principal mask layers, namely, the yields of the respective processes. Therefore, the TAT of the DRAM process development, the yield improvement, the failure analysis or the like can be shortened.

More specifically, the invention related to a test group element used for obtaining a yield of a DRAM portion of an electronic device such as a semiconductor device is very useful for the DRAM process development and process control owing to its effect that yields of respective principal processes can be calculated in short TAT.

### BRIEF DESCRIPTION OF THE DRAWINGS

FIG. 1 is a plan view of a DRAM portion of an integrated circuit device to be evaluated for the yield.

FIG. 2 is a plan view of the DRAM portion of the integrated circuit device to be evaluated for the yield.

FIG. 3 is a cross-sectional view taken on line III-III of FIGS. 1 and 2.

FIG. 4 is a cross-sectional view taken on line IV-IV of FIGS. 1 and 2.

FIG. 5 is a plan view of a TEG for detecting an X-direction short between storage plates according to an embodiment of the invention.

FIG. 6 is a cross-sectional view taken on line VI-VI of FIG. 5.

FIG. 7 is a plan view of a TEG for detecting a Y-direction short between storage plates according to the embodiment of the invention.

FIG. 8 is a cross-sectional view taken on line VIII-VIII of FIG. 7.

FIG. 9 is a plan view of a TEG for detecting a short between an upper cell plate and a metal interconnect contact according to the embodiment of the invention.

FIG. 10 is a cross-sectional view taken on line X-X of FIG. 9.

FIG. 11 is a plan view of a TEG for detecting an open between a storage plate and a source contact according to the embodiment of the invention.

FIG. 12 is a cross-sectional view taken on line XII-XII of FIG. 11.

FIG. 13 is a plan view of a TEG for detecting an open between a source contact and a metal interconnect contact according to the embodiment of the invention.

FIG. 14 is a cross-sectional view taken on line XIV-XIV of FIG. 13.

FIG. 15 is a plan view of a TEG for detecting a short between source contacts according to the embodiment of the invention.

FIG. 16 is a cross-sectional view taken on line XVI-XVI of FIG. 15.

### DETAILED DESCRIPTION OF THE INVENTION EMBODIMENT

A DRAM yield calculation TEG and a yield calculation method using the same according to an embodiment of the invention will now be described with reference to the accompanying drawings. Each DRAM yield calculation TEG of this embodiment described below is formed by providing a necessary interconnect to a mask layer disposed on or beneath a target mask layer to be calculated for the yield, so that the yield of a DRAM portion of an integrated circuit device can be obtained as a product of yields (fraction defectives) attained in processes respectively corresponding to principal mask layers.

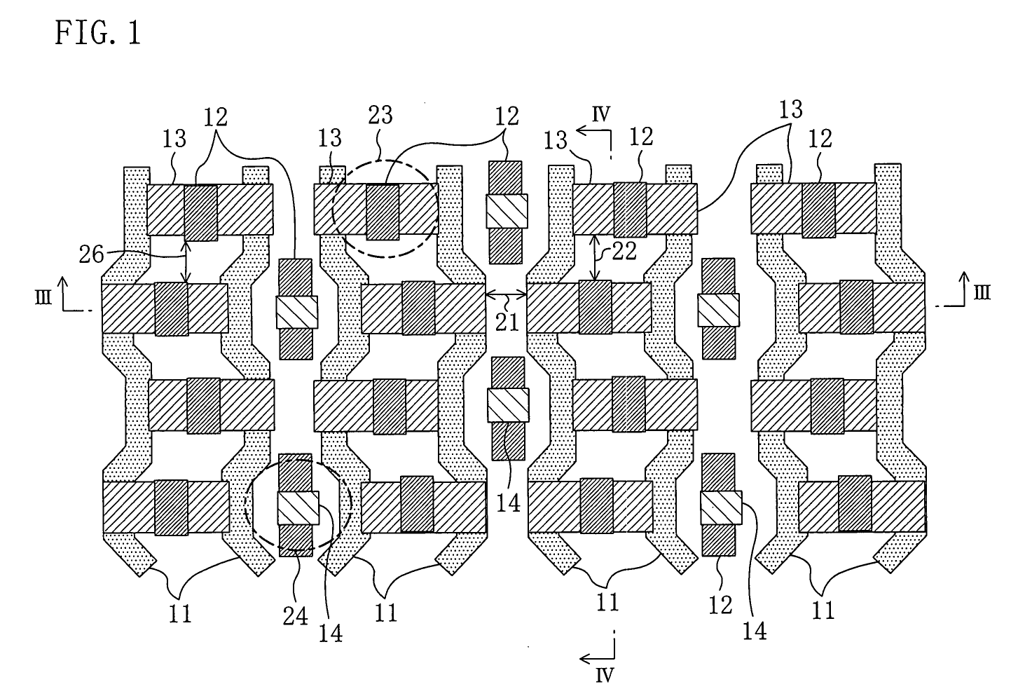

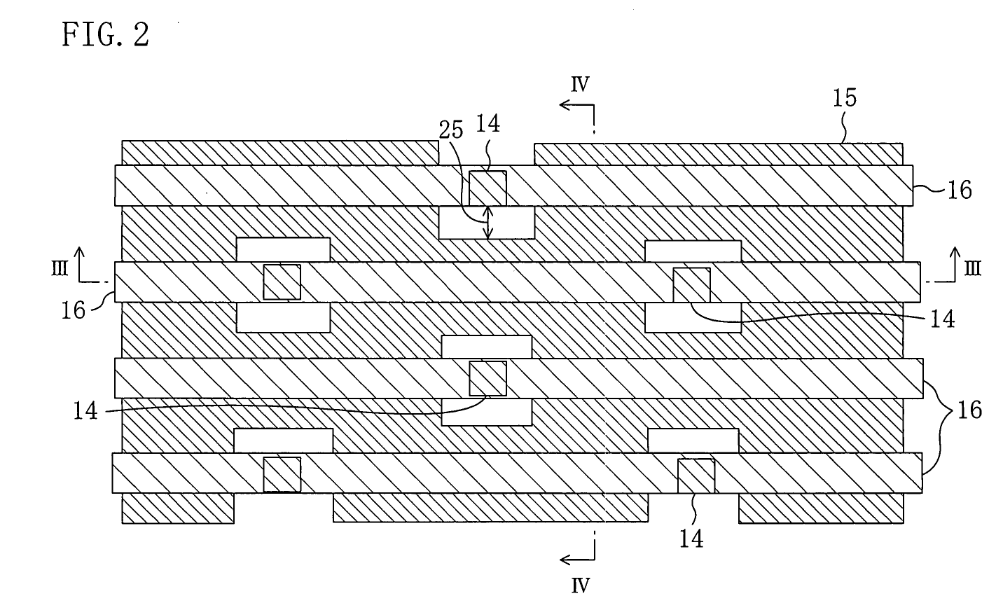

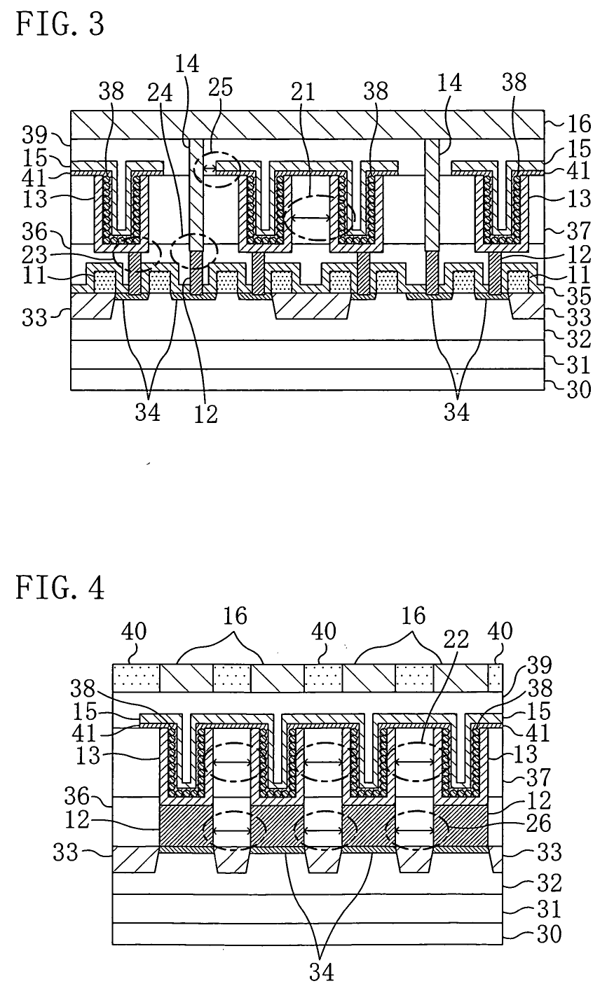

FIGS. 1 and 2 show the plane structure of the DRAM portion of the integrated circuit device to be evaluated for the yield, and specifically, FIG. 1 is a plan view of a layer where a storage plate of a capacitor is provided and a layer disposed beneath this layer, and FIG. 2 is a plan view of a layer where an upper cell plate of the capacitor is provided and a layer disposed on this layer. It is noted that part of elements such as an interlayer insulating film is omitted. Also, FIG. 3 is a cross-sectional view taken on line III-III of FIGS. 1 and 2 and FIG. 4 is a cross-sectional view taken on line IV-IV of FIGS. 1 and 2.

As shown in FIGS. 1 through 4, gate interconnects (word lines) 11 are formed on a semiconductor substrate 30 including an N-type well (lower layer) 31 and a P-type well (upper layer) 32 and partitioned by an isolation 33. Source/drain regions 34 are formed on both sides of each gate interconnect 11 in the P-type well 32. An insulating film 35 and an interlayer insulating film 36 are successively formed so as to cover the gate interconnects 11. A source contact 12 connected to the source/drain region 34 is formed in the insulating film 35 and the interlayer insulating film 36. An interlayer insulating film 37 having a capacitor forming recess is formed on the interlayer insulating film 36, and a storage plate (lower electrode) 13 connected to a given source contact 12 is formed on the inner wall and the bottom of the recess. Specifically, after forming a flat electrode portion (lower electrode 13) made of, for example, a doped polysilicon film within the recess, a nucleus of a spherical projection made of, for example, a non-doped amorphous silicon film is formed, and thereafter, the spherical projection 38 is formed on the lower electrode 13 by LP (low pressure)-HSG (hemi spherical grained) technique. The spherical projection 38 is doped with, for example, phosphorus (P) so as to give an n-type conductivity. Thereafter, a capacitor dielectric film 41 is formed so as to cover the storage plate 13 on which the spherical projection 38 is provided. An upper cell plate 15 is formed on the capacitor dielectric film 41 and the interlayer insulating film 37 excluding a portion where a metal interconnect contact is formed. An interlayer insulating film 39 is formed so as to cover the upper cell plate 15. A metal interconnect contact (bit line contact) 14 connected to a given source contact 12 is formed in the interlayer insulating film 37 and the interlayer insulating film 39. An interlayer insulating film 40 is formed on the interlayer insulating film 39, and a metal interconnect (bit line) 16 connected to the metal interconnect contact 14 is buried in the interlayer insulating film 40.

Failures possibly caused in the DRAM portion shown in FIGS. 1 through 4 are an X-direction (for example, a bit line direction; which is also applied to description below) short 21 between storage plates, a Y-direction (for example, a word line direction; which is also applied to the description below) short 22 between storage plates, an open 23 between a storage plate and a source contact, an open 24 between a source contact and a metal interconnect contact, a short 25 between an upper cell plate and a metal interconnect contact and a short 26 between source contacts.

Now, the layout of each DRAM yield calculation TEG according to this embodiment used for selectively detecting each of the aforementioned failures will be described.

[TEG for Detecting X-Direction Short Between Storage Plates]

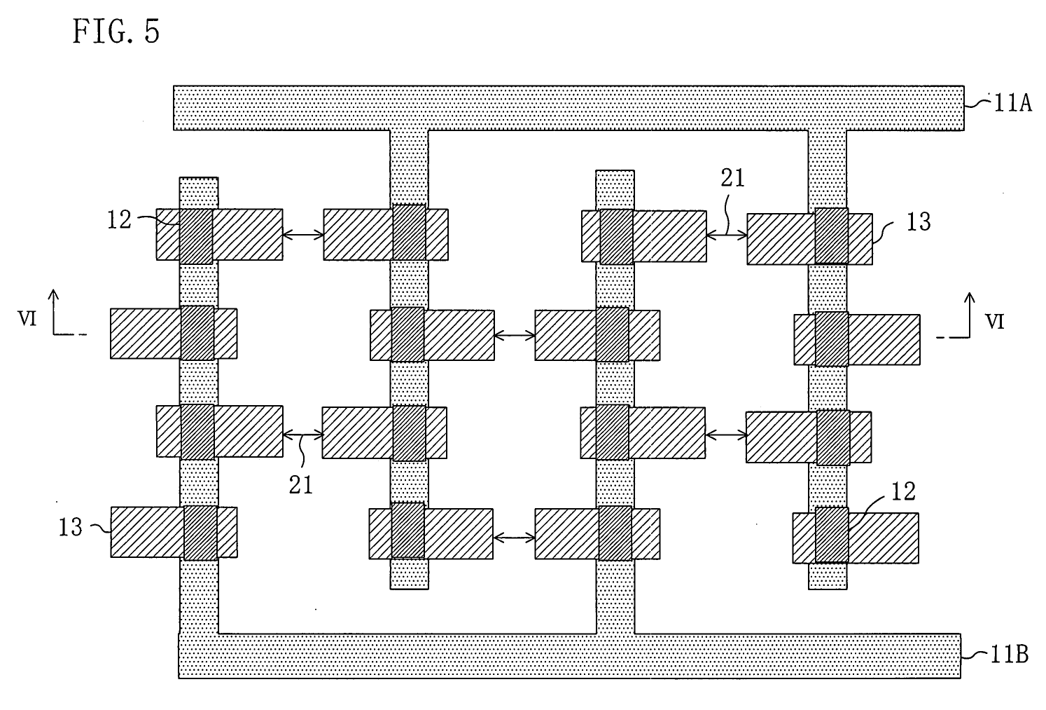

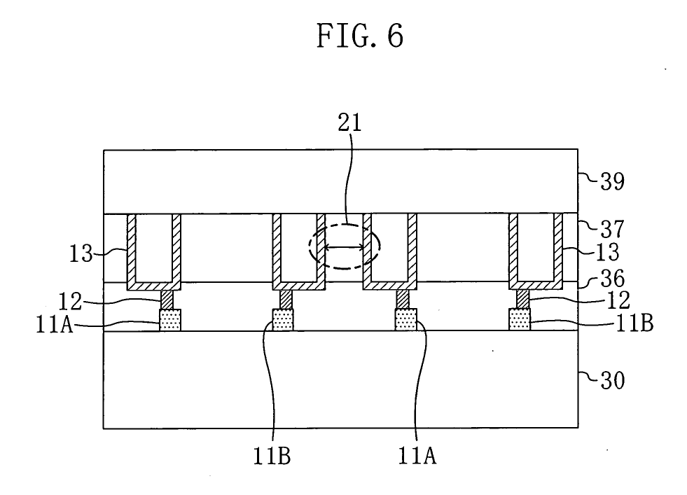

FIG. 5 is a plan view of a TEG for detecting an X-direction short between storage plates according to this embodiment and FIG. 6 is a cross-sectional view taken on line VI-VI of FIG. 5. In FIGS. 5 and 6, like reference numerals are used to refer to elements corresponding to the elements of the DRAM portion shown in FIGS. 1 through 4 so as to avoid redundant description.

As shown in FIGS. 5 and 6, in the TEG for detecting an X-direction short between storage plates of this embodiment, a first evaluation gate interconnect 11A and a second evaluation gate interconnect 11B are provided to a layer corresponding to a layer of the gate interconnect 11 of the DRAM portion. The first evaluation gate interconnect 11A is connected to one of a pair of storage plates 13 adjacent to each other in the X-direction (that is, a first evaluation storage plate) through a source contact (that is, a first evaluation source contact) 12. The second evaluation gate interconnect 11B is connected to the other of the pair of the storage plates 13 (that is, a second evaluation storage plate) through a source contact (that is, a second evaluation source contact) 12.

The TEG shown in FIGS. 5 and 6 is not particularly specified in the number or the shape of the evaluation gate interconnects 11, the number or the shape of the evaluation source contacts 12 or the evaluation storage plates 13 provided on or above the evaluation gate interconnects 11, and the number, the thickness or the like of stacked interlayer insulating films as far as the layout space between evaluation storage plates 13 in the X-direction is designed to be equivalent to that in the DRAM portion of FIGS. 1 through 4. Also, a spherical projection 38 similar to that of the integrated circuit device to be evaluated for the yield shown in FIGS. 1 through 4 may be provided on the evaluation storage plate 13.

When the TEG of FIGS. 5 and 6 is used, occurrence probability of the X-direction short 21 between storage plates, namely, the yield attained in forming storage plates, can be evaluated by evaluating whether or not a short is caused between the first evaluation gate interconnect 11A and the second evaluation gate interconnect 11B.

[TEG for Detecting Y-Direction Short Between Storage Plates]

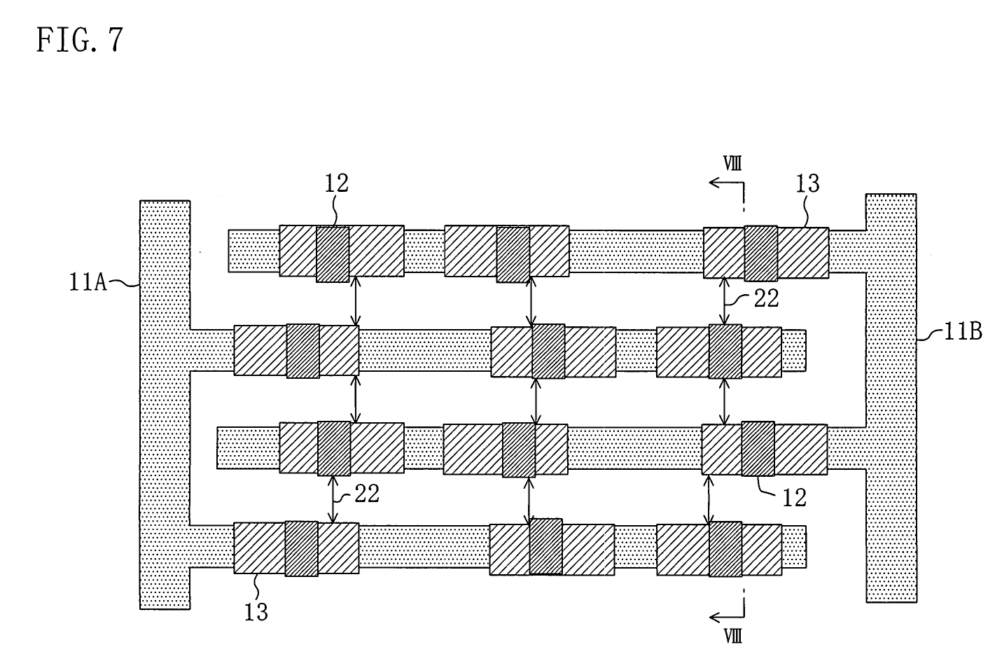

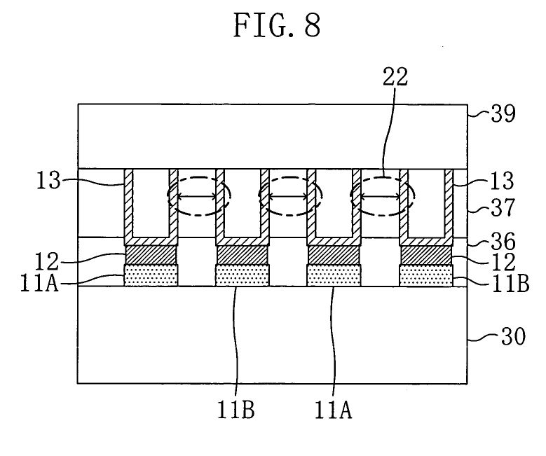

FIG. 7 is a plan view of a TEG for detecting a Y-direction short between storage plates according to this embodiment and FIG. 8 is a cross-sectional view taken on line VIII-VIII of FIG. 7. In FIGS. 7 and 8, like reference numerals are used to refer to elements corresponding to the elements of the DRAM portion shown in FIGS. 1 through 4 so as to avoid redundant description.

As shown in FIGS. 7 and 8, in the TEG for detecting a Y-direction short between storage plates of this embodiment, a first evaluation gate interconnect 11A and a second evaluation gate interconnect 11B are provided to a layer corresponding to a layer of the gate interconnect 11 of the DRAM portion. The first evaluation gate interconnect 11A is connected to one of a pair of storage plates 13 adjacent to each other in the Y-direction (that is, a first evaluation storage plate) through a source contact (that is, a first evaluation source contact) 12. The second evaluation gate interconnect 11B is connected to the other of the pair of the storage plates 13 (that is, a second evaluation storage plate) through a source contact (that is, a second evaluation source contact) 12.

The TEG shown in FIGS. 7 and 8 is not particularly specified in the number or the shape of the evaluation gate interconnects 11, the number or the shape of the evaluation source contacts 12 or the evaluation storage plates 13 provided on or above the evaluation gate interconnects 11, and the number, the thickness or the like of stacked interlayer insulating films as far as the layout space between evaluation storage plates 13 in the Y-direction is designed to be equivalent to that in the DRAM portion of FIGS. 1 through 4. Also, a spherical projection 38 similar to that of the integrated circuit device to be evaluated for the yield shown in FIGS. 1 through 4 may be provided on the evaluation storage plate 13.

When the TEG of FIGS. 7 and 8 is used, occurrence probability of the Y-direction short 22 between storage plates, namely, the yield attained in forming storage plates, can be evaluated by evaluating whether or not a short is caused between the first evaluation gate interconnect 11A and the second evaluation gate interconnect 11B.

[TEG for Detecting Short Between Upper Cell Plate and Metal Interconnect Contact]

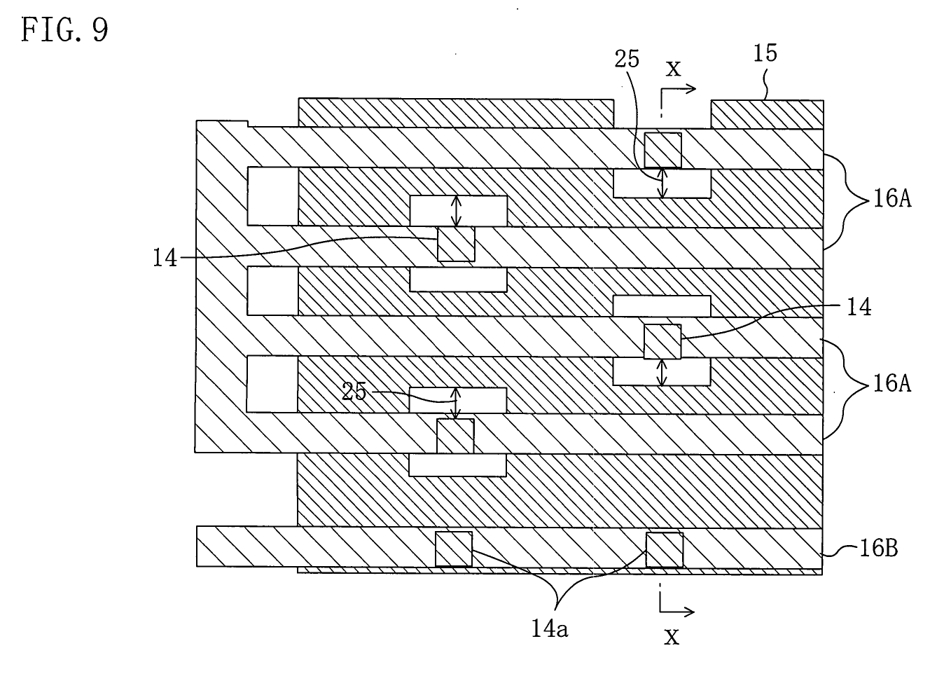

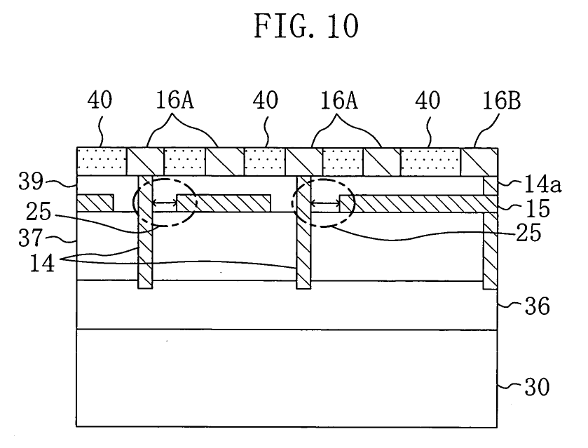

FIG. 9 is a plan view of a TEG for detecting a short between an upper cell plate and a metal interconnect contact according to this embodiment and FIG. 10 is a cross-sectional view taken on line X-X of FIG. 9. In FIGS. 9 and 10, like reference numerals are used to refer to elements corresponding to the elements of the DRAM portion shown in FIGS. 1 through 4 so as to avoid redundant description.

As shown in FIGS. 9 and 10, in the TEG for detecting a short between an upper cell plate and a metal interconnect contact of this embodiment, a first evaluation metal interconnect 16A and a second evaluation metal interconnect 16B are provided to a layer corresponding to a layer of the metal interconnect (bit line) 16 of the DRAM portion. The first evaluation metal interconnect 16A is connected to a metal interconnect contact (that is, a first evaluation metal interconnect contact) 14. The second evaluation metal interconnect 16B is electrically connected to an upper cell plate (that is, an evaluation upper cell plate) 15 through a dummy contact 14a.

The TEG shown in FIGS. 9 and 10 is not particularly specified in the number or the shape of the evaluation metal interconnects 16, the number or the shape of the evaluation metal interconnect contacts 14 or the evaluation upper cell plates 15 connected to the evaluation metal interconnects 16, and the number, the thickness or the like of stacked interlayer insulating films as far as the layout space between the evaluation metal interconnect contact 14 and the evaluation upper cell plate 15 is designed to be equivalent to that in the DRAM portion of FIGS. 1 through 4.

When the TEG of FIGS. 9 and 10 is used, occurrence probability of the short 25 between an upper cell plate and a metal interconnect contact, namely, the yield attained in forming upper cell plates or metal interconnect contacts, can be evaluated by evaluating whether or not a short is caused between the first evaluation metal interconnect 16A and the second evaluation metal interconnect 16B.

[TEG for Detecting Open Between Storage Plate and Source Contact]

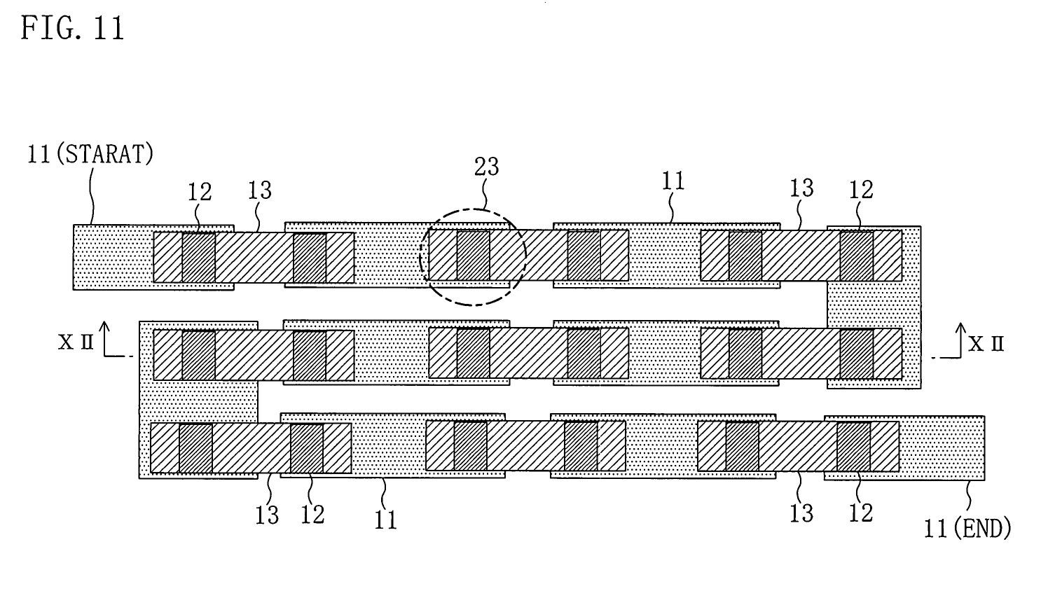

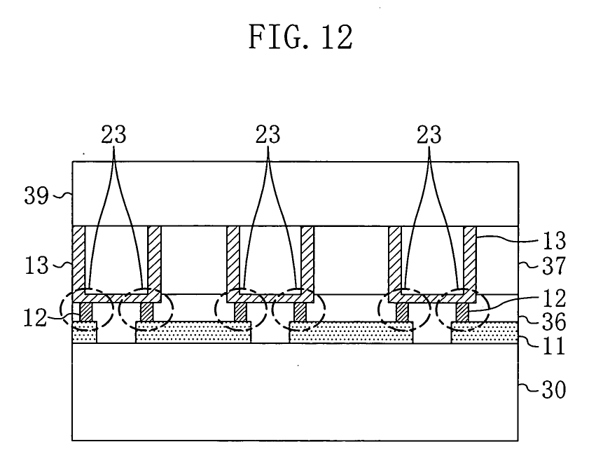

FIG. 11 is a plan view of a TEG for detecting an open between a storage plate and a source contact according to this embodiment and FIG. 12 is a cross-sectional view taken on line XII-XII of FIG. 11. In FIGS. 11 and 12, like reference numerals are used to refer to elements corresponding to the elements of the DRAM portion shown in FIGS. 1 through 4 so as to avoid redundant description.

As shown in FIGS. 11 and 12, in the TEG for detecting an open between a storage plate and a source contact of this embodiment, a plurality of evaluation gate interconnects 11 are provided to a layer corresponding to a layer of the gate interconnect 11 of the DRAM portion. The plural evaluation gate interconnects 11 are electrically connected to one another through a plurality of source contacts (that is, evaluation source contacts) 12 respectively connected to the evaluation gate interconnects 11 and a plurality of storage plates (that is, evaluation storage plates) 13 respectively connected to the evaluation source contacts 12. In other words, the TEG shown in FIGS. 11 and 12 has a chain structure.

The TEG shown in FIGS. 11 and 12 is not particularly specified in the number or the shape of the evaluation gate interconnects 11, the number or the shape of the evaluation source contacts 12 or the evaluation storage plates 13 provided on or above the evaluation gate interconnects 11, and the number, the thickness or the like of stacked interlayer insulating films. For example, the size (specifically, the area in the plan view) of each evaluation source contact 12 and the interlayer insulating film 36 may be set to be equivalent to those in the integrated circuit device to be evaluated for the yield shown in FIGS. 1 through 4. Also, a spherical projection 38 similar to that of the integrated circuit device to be evaluated for the yield shown in FIGS. 1 through 4 may be provided on the evaluation storage plate 13.

When the TEG of FIGS. 11 and 12 is used, occurrence probability of the open 23 between a storage plate and a source contact, namely, the yield in forming source contacts or storage plates, can be evaluated by evaluating the resistance of the chain structure, and more specifically, by evaluating the resistance between an evaluation gate interconnect 11 (START) disposed at one end of the chain structure and another evaluation gate interconnect 11 (END) disposed at the other end of the chain structure.

[TEG for Detecting Open Between Source Contact and Metal Interconnect Contact]

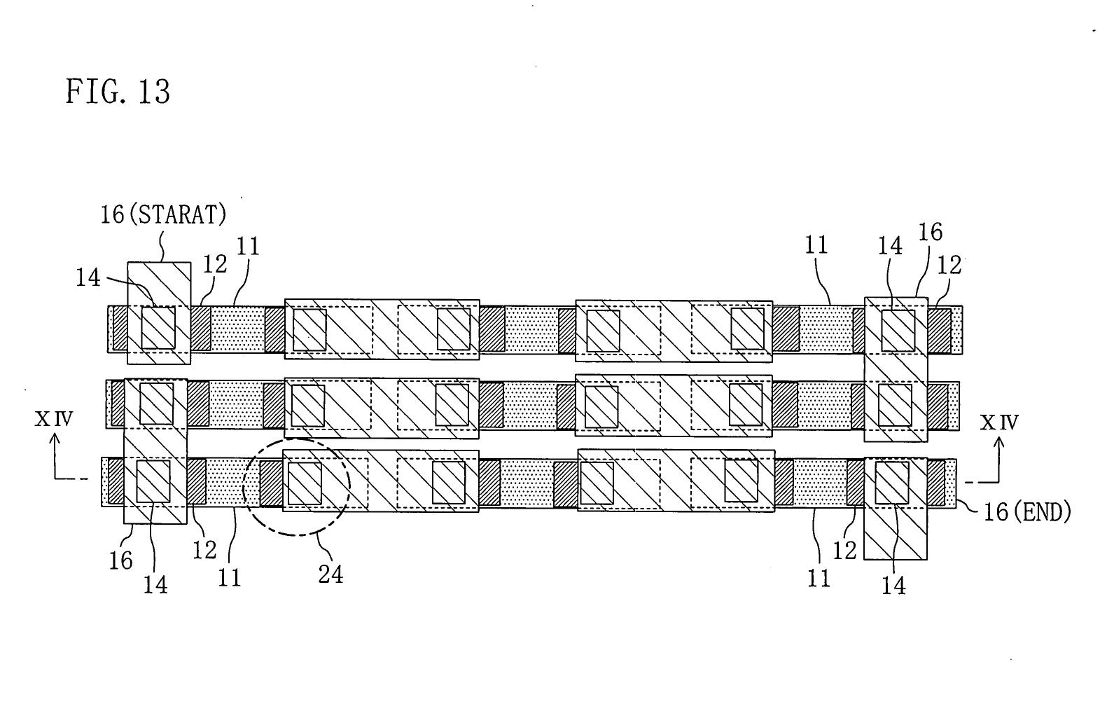

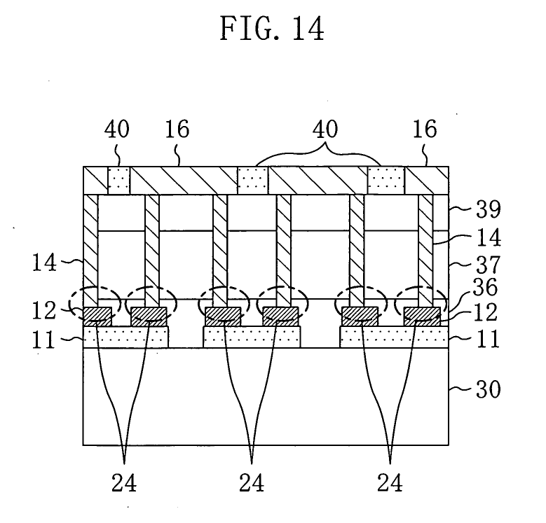

FIG. 13 is a plan view of a TEG for detecting an open between a source contact and a metal interconnect contact according to this embodiment and FIG. 14 is a cross-sectional view taken on line XIV-XIV of FIG. 13. In FIGS. 13 and 14, like reference numerals are used to refer to elements corresponding to the elements of the DRAM portion shown in FIGS. 1 through 4 so as to avoid redundant description.

As shown in FIGS. 13 and 14, in the TEG for detecting an open between a source contact and a metal interconnect contact of this embodiment, a plurality of evaluation gate interconnects 11 are provided to a layer corresponding to a layer of the gate interconnect 11 of the DRAM portion. The plural evaluation gate interconnects 11 are electrically connected to one another through a plurality of source contacts (that is, evaluation source contacts) 12 respectively connected to the evaluation gate interconnects 11, a plurality of metal interconnect contacts (that is, evaluation metal interconnect contacts) 14 respectively connected to the evaluation source contacts 12 and a plurality of metal interconnects (that is, evaluation metal interconnects) 16 respectively connected to the evaluation metal interconnect contacts 14. In other words, the TEG shown in FIGS. 13 and 14 has a chain structure.

The TEG shown in FIGS. 13 and 14 is not particularly specified in the number or the shape of the evaluation gate interconnects 11, the number or the shape of the evaluation source contacts 12, the evaluation metal interconnect contacts 14 or the evaluation metal interconnects 16 provided on or above the evaluation gate interconnects 11, and the number, the thickness or the like of stacked interlayer insulating films. For example, the size (specifically, the area in the plan view) of each evaluation source contact 12 and the width of each evaluation metal interconnect 16 may be set to be equivalent to those in the integrated circuit device to be evaluated for the yield shown in FIGS. 1 through 4.

When the TEG of FIGS. 13 and 14 is used, occurrence probability of the open 24 between a source contact and a metal interconnect contact, namely, the yield in forming source contacts or metal interconnect contacts, can be evaluated by evaluating the resistance of the chain structure, and more specifically, by evaluating the resistance between an evaluation metal interconnect 16 (START) disposed at one end of the chain structure and another evaluation metal interconnect 16 (END) disposed at the other end of the chain structure.

[TEG for Detecting Short Between Source Contacts]

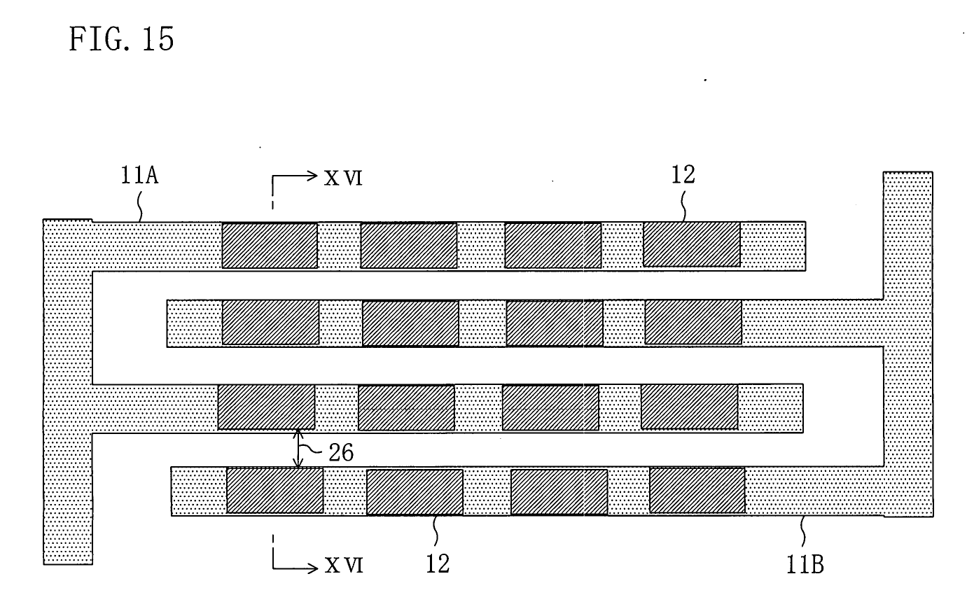

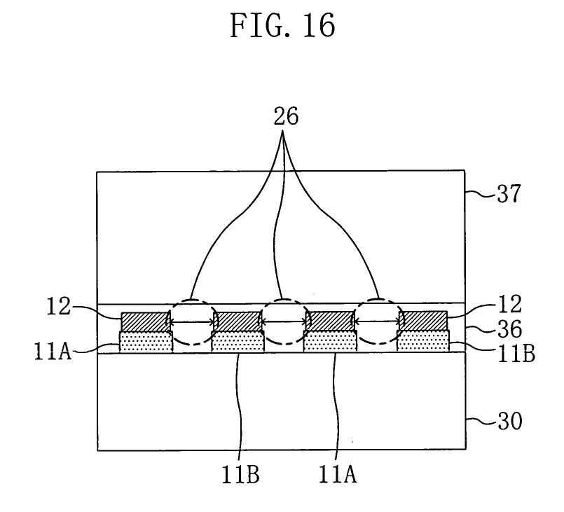

FIG. 15 is a plan view of a TEG for detecting a short between source contacts according to this embodiment and FIG. 16 is a cross-sectional view taken on line XVI-XVI of FIG. 15. In FIGS. 15 and 16, like reference numerals are used to refer to elements corresponding to the elements of the DRAM portion shown in FIGS. 1 through 4 so as to avoid redundant description.

As shown in FIGS. 15 and 16, in the TEG for detecting a short between source contacts of this embodiment, a first evaluation gate interconnect 11A and a second evaluation gate interconnect 11B are provided to a layer corresponding to a layer of the gate interconnect 11 of the DRAM portion. One of a pair of source contacts 12 adjacent to each other in, for example, the Y-direction (that is, a first evaluation source contact) is formed on the first evaluation gate interconnect 11A and the other of the pair of source contacts 12 (that is, a second evaluation source contact) is formed on the second evaluation gate interconnect 11B.

The TEG shown in FIGS. 15 and 16 is not particularly specified in the number or the shape of the evaluation gate interconnects 11, the number or the shape of the evaluation source contacts 12 provided on the evaluation gate interconnects 11, and the number, the thickness or the like of stacked interlayer insulating films as far as the layout space between the source contacts 12 in the Y-direction is designed to be equivalent to that in the DRAM portion of FIGS. 1 through 4.

When the TEG of FIGS. 15 and 16 is used, occurrence probability of the short 26 between source contacts, namely, the yield in forming source contacts, can be evaluated by evaluating whether or not a short is caused between the first evaluation gate interconnect 11A and the second evaluation gate interconnect 11B.

As described above, when the respective failure detecting TEGs of this embodiment are used, the yields attained in principal layers (namely, in principal processes) or principal failure items in the DRAM capacitor forming process can be respectively calculated. As a result, the yield of the DRAM portion of the integrated circuit device (i.e., the actual product) can be obtained as a product of the yields attained in the principal mask layers, namely, the yields of the respective processes, and therefore, TAT of DRAM process development, yield improvement or defect analysis can be shortened.

Furthermore, in the actual yield evaluation, when, for example, 300 failure detecting TEGs of this embodiment each of approximately 320 kb (namely, corresponding to 320 k capacitor cells) are provided to each of, for example, 50 chips formed on one wafer, namely, when TEGs of 320 kb in the number of 15000 in total are provided on one wafer, the yield can be highly precisely evaluated. As a result, it is possible to calculate a soft open yield (or a soft short yield) separately from a hard open yield (or a hard short yield) in consideration of the device characteristics on the basis of, for example, a resistance value actually measured by using the TEG For example, in the case where the average resistance is approximately 100Ω, a resistance value not less than 10 kΩ and less than 1 MΩ may be defined as a soft open failure and a resistance value not less than 1 MΩ may be defined as a hard open failure.

Moreover, when the fraction defective per unit capacity attained in each principal layer or each principal failure item is calculated by using the evaluation results obtained by using the failure detecting TEGs of this embodiment, the yield of a DRAM portion of an actual product (integrated circuit device) can be estimated on the basis of the capacity of the DRAM portion. At this point, the yield of the DRAM portion can be obtained separately with respect to respective principal layers (respective principal processes) or principal failure items.

With respect to the portion of the integrated circuit device other than the DRAM portion, a critical area and the yield attained in each process can be obtained on the basis of the actual layout of the integrated circuit device by a conventionally widely employed method such as a geometry method or a Monte Carlo method, and the yield of the portion can be estimated based on data thus obtained. When a product of the yield of the portion other than the DRAM portion thus obtained and the yields attained in the principal layers or the principal failure items obtained by using the DRAM yield calculation TEGs of this embodiment is obtained, the yield of the whole integrated circuit device including the DRAM portion, namely, the yield of the actual product, can be estimated.

Furthermore, when the yields attained in the respective layers are evaluated by using the DRAM yield calculation TEGs of this embodiment, the respective processes for forming the DRAM can be developed in parallel, and hence, TAT of the development can be shortened.

In tests for DRAMs, failures are classified into failure categories of a single bit failure, a bit pair failure, a bit line (BL) failure and the like by a method of, for example, the bit failure map analysis. When such categories (namely, the yields of respective failure items of the actual product) and the yields attained in the principal layers or principal failure items obtained by the DRAM yield calculation TEGs of this embodiment (namely, the fraction defectives) are previously related to each other, the yields of the actual product attained in the respective processes can be calculated on the basis of the yields of the failure items of the actual product obtained by the bit failure map analysis. Specifically, even when the yield is lowered due to any process trouble or the like occurring in fabrication or mass-production of the actual product, a process possibly causing the trouble can be presumed on the basis of the result of the bit failure map analysis, and hence, the trouble can be coped with at an early stage.

Specifically, the X-direction short 21 between storage plates shown in FIGS. 5 and 6 and the Y-direction short 22 between storage plates shown in FIGS. 7 and 8 can be causes of pair bit failures in the X-direction and the Y-direction, respectively, the open 23 between a storage plate and a source contact shown in FIGS. 11 and 12 can be a cause of a single bit failure, and the short 25 between an upper cell plate and a metal interconnect contact shown in FIGS. 9 and 10 can be a cause of a bit line failure. When the relationship between failures and failure items are thus defined and the relationships between the yields obtained by using the DRAM yield calculation TEGs of this embodiment and the yields of the respective failure items of the actual product obtained by the bit failure map analysis are previously obtained, the yields attained in respective layers (respective processes) can be calculated on the basis of the result of the bit failure map analysis (i.e., the yields of the failure items of the actual product). Also, the result can be used in the process control, and when the yield is lowered in the fabrication or mass-production of the actual product, the defective process can be analyzed and found at an early stage so as to be rapidly coped with.

What is claimed is:

1. An evaluation semiconductor device for evaluating a yield of a DRAM portion of an integrated circuit device, comprising:
an evaluation gate interconnect provided in a layer corresponding to a gate interconnect layer of said DRAM portion; and
an evaluation source contact corresponding to a source contact of a capacitor included in said DRAM portion and connected to said evaluation gate interconnect.

2. The evaluation semiconductor device of claim 1, further comprising a plurality of elements of said capacitor provided on or above said evaluation gate interconnect.

3. The evaluation semiconductor device of claim 1,
wherein said evaluation gate interconnect includes at least a first evaluation gate interconnect and a second evaluation gate interconnect,
said evaluation source contact includes at least a first evaluation source contact connected to said first evaluation gate interconnect and a second evaluation source contact connected to said second evaluation gate interconnect, and
evaluation storage plates corresponding to a storage plate of said capacitor are respectively formed on said first evaluation source contact and said second evaluation source contact.

4. The evaluation semiconductor device of claim 1,
wherein said evaluation gate interconnect includes at least a first evaluation gate interconnect and a second evaluation gate interconnect,
said evaluation source contact includes at least a first evaluation source contact connected to said first evaluation gate interconnect and a second evaluation source contact connected to said second evaluation gate interconnect, and
an evaluation storage plate corresponding to a storage plate of said capacitor is formed for connecting said first evaluation source contact and said second evaluation source contact to each other.

5. The evaluation semiconductor device of claim 1,
wherein said evaluation gate interconnect includes at least a first evaluation gate interconnect and a second evaluation gate interconnect,
said evaluation source contact includes at least a first evaluation source contact connected to said first evaluation gate interconnect and a second evaluation source contact connected to said second evaluation gate interconnect,
an evaluation bit line corresponding to a bit line of said DRAM portion is formed for electrically connecting said first evaluation source contact and said second evaluation source contact to each other,
said first evaluation source contact and said evaluation bit line are connected to each other through a first evaluation bit line contact corresponding to a bit line contact of said DRAM portion, and
said second evaluation source contact and said evaluation bit line are connected to each other through a second evaluation bit line contact corresponding to the bit line contact of said DRAM portion.

6. The evaluation semiconductor device of claim 1,
wherein said evaluation gate interconnect includes at least a first evaluation gate interconnect and a second evaluation gate interconnect, and
said evaluation source contact includes at least a first evaluation source contact formed on said first evaluation gate interconnect and a second evaluation source contact formed on said second evaluation gate interconnect.

7. An evaluation semiconductor device for evaluating a yield of a DRAM portion of an integrated circuit device, comprising:
a first evaluation bit line and a second evaluation bit line provided in a layer corresponding to a bit line layer of said DRAM portion,
wherein said first evaluation bit line is electrically connected to an evaluation bit line contact corresponding to a bit line contact of said DRAM portion and said second evaluation bit line is electrically connected to an evaluation upper cell plate corresponding to an upper cell plate of a capacitor included in said DRAM portion.
